(19) United States
(12) Patent Application Publication
(10) Pub. No.: US 2017/0069526 A1
(43) Pub. Date: Mar. 9, 2017

(54) CHUCK ASSEMBLY WITH TILTABLE CHUCK AND SEMICONDUCTOR FABRICATION SYSTEM INCLUDING THE SAME

(71) Applicants: Jongsoon PARK, Suwon-si (KR); Jong-Kyu KIM, Seongnam-si (KR); Jung-Ik OH, Hwaseong-si (KR); Sang-Kuk KIM, Seongnam-si (KR); Jongchul PARK, Seongnam-si (KR)

(72) Inventors: Jongsoon PARK, Suwon-si (KR); Jong-Kyu KIM, Seongnam-si (KR); Jung-Ik OH, Hwaseong-si (KR); Sang-Kuk KIM, Seongnam-si (KR); Jongchul PARK, Seongnam-si (KR)

(21) Appl. No.: 15/170,151

(22) Filed: Jun. 1, 2016

(30) Foreign Application Priority Data
Sep. 3, 2015 (KR) 10-2015-0124939

(51) Int. Cl. H01L 21/687; H01J 37/305; H01L 21/263

(52) U.S. Cl. CPC H01L 21/68764; H01L 21/2633; H01J 37/3056

(57) ABSTRACT

A chuck assembly includes a chuck to hold a substrate, and a pillar coupled to the chuck to support the chuck, an axis of the pillar passing through a center of the pillar in a longitudinal direction of the pillar, wherein the chuck has a top surface, which is inclined with respect to the axis of the pillar, the top surface of the chuck being precessionally rotatable about the axis of the pillar.

### CROSS-REFERENCE TO RELATED APPLICATION

Korean Patent Application No. 10-2015-0124939, filed on Sep. 3, 2015, in the Korean Intellectual Property Office, and entitled: “Chuck Assembly with Tiltable Chuck and Semiconductor Fabrication System Including the Same,” is incorporated by reference herein in its entirety.

### BACKGROUND

1. Field

The present disclosure relates to a semiconductor fabrication system, and in particular, to a chuck assembly with a tiltable chuck and a semiconductor fabrication system including the same.

2. Description of the Related Art

In the case where a directional ion beam is used to perform an etching process on a tilted substrate, it is possible to form a pattern with a vertical profile. In such an ion-beam etching process, the substrate is generally fixedly maintained at a predetermined tilted angle of a chuck.

### SUMMARY

Some embodiments provide a chuck assembly, which is configured to be able to change a tilting angle of a chuck with ease, and a semiconductor fabrication system including the same.

Some embodiments provide a chuck assembly, which is configured to be able to achieve high etching uniformity in an etching process, and a semiconductor fabrication system including the same.

According to some aspects of embodiments, a chuck assembly may be configured to allow a chuck holding a substrate to rotate in an inclined state, and a semiconductor fabrication system including the chuck assembly is provided.

According to some aspects of embodiments, the chuck assembly may be configured to allow the substrate to rotate along with the chuck and to allow a center of the substrate to undergo a precessional motion about an axis of the pillar.

According to some aspects of embodiments, the chuck assembly may be configured to allow the substrate to rotate along with the chuck and to allow the center of the substrate to be placed on the axis of the chuck.

According to some aspects of embodiments, the chuck assembly may be configured to be able to change an inclination angle of the chuck.

According to some aspects of embodiments, an ion beam source may be configured to revolve around the chuck, at a variable or fixed inclination angle.

According to some embodiments, a chuck assembly may include a chuck to hold a substrate, and a pillar coupled to the chuck to support the chuck, an axis of the pillar passing through a center of the pillar in a longitudinal direction of the pillar, wherein the chuck has a top surface, which is inclined with respect to the axis of the pillar, the top surface of the chuck being precessionally rotatable about the axis of the pillar.

In some embodiments, the chuck may have an axis passing through a center of the chuck, and the axis of the chuck may be inclined with respect to the axis of the pillar.

In some embodiments, the chuck may undergo the precessional motion in such a way that the axis thereof revolves around the axis of the pillar in a state of being inclined with respect to the axis of the pillar.

In some embodiments, the chuck may be configured to rotate on the axis of the chuck.

In some embodiments, the chuck may be configured to allow the axis thereof to pass through a center of the substrate disposed on the chuck.

In some embodiments, the chuck may be configured to allow the center of the substrate to revolve around the axis of the pillar.

In some embodiments, the center of the substrate may be located on the axis of the pillar.

In some embodiments, the pillar may be configured to rotate on the axis of the pillar.

In some embodiments, the chuck assembly may further include a connecting portion, which is provided to be rotatable about the pillar and to connect the chuck to the pillar. The connecting portion may be fixedly connected to the chuck, and an angle between the axes of the chuck and the pillar may be controlled by changing a rotation angle of the connecting portion.

In some embodiments, the chuck assembly may further include a connecting portion connecting the chuck to the pillar. The connecting portion may be provided to be rotatable about the pillar, and an angle between the axes of the chuck and the pillar may be controlled by changing a rotation angle of the connecting portion.

In some embodiments, the connecting portion may include a supporting frame, and the supporting frame may include a horizontal frame passing through the pillar in a direction orthogonal to the axis of the pillar and a vertical frame provided on opposite ends of the horizontal frame. The vertical frame may extend parallel to the axis of the pillar, and the vertical frame may be configured to be rotatable about an axis of the horizontal frame.

In some embodiments, the chuck assembly may further include a horizontal rod, which is provided to connect the supporting frame to the chuck and to pass through the chuck in a direction orthogonal to the axis of the chuck. The chuck may be configured to be rotatable about the horizontal rod.

According to some embodiments, a chuck assembly may include a chuck holding a substrate, the substrate being exposed to an ion beam propagating in a vertical direction, a pillar coupled to the chuck to support the chuck, and a connecting portion configured to allow the chuck to be rotatably connected to the pillar. The connecting portion may be configured in such a way that rotation of the connecting portion allows the chuck to be inclined with respect to an axis of the pillar, which passes through a center of the pillar in the vertical direction. The chuck may undergo a precessional motion about the pillar.

In some embodiments, the chuck may have an axis passing therethrough in the vertical direction, and the connecting portion may be configured to allow the axis of the chuck to be inclined with respect to the axis of the pillar, when the connecting portion is rotated.

In some embodiments, the connecting portion may include a rotation ball that is provided between the chuck and the pillar, and the rotation ball may be fixedly connected to the chuck and may be rotatably connected to the pillar. The rotation ball may be configured to allow the chuck to undergo a precessional motion about the axis of the pillar in a state of being inclined with respect to the axis of the pillar, when the rotation ball is rotated.

In some embodiments, the connecting portion may include a supporting frame rotatably connected to the pillar and a connection rod rotatably connected to the chuck. At least one of the supporting frame and the connection rod may be configured to allow the chuck to be inclined with respect to the axis of the pillar, when the at least one of the supporting frame and the connection rod is rotated.

In some embodiments, the supporting frame may include a horizontal frame passing through an upper end portion of the pillar adjacent to the chuck in a direction orthogonal to the axis of the pillar and a vertical frame connected to opposite ends of the horizontal frame. The vertical frame may extend parallel to the axis of the pillar, and the vertical frame may be connected to opposite ends of the connection rod.

In some embodiments, the connection rod may extend in a direction orthogonal to the axis of the chuck, and the chuck may be configured to be able to rotate about the connection rod and to be inclined with respect to the axis of the pillar.

In some embodiments, the pillar may be configured to rotate on the axis of the pillar.

According to some embodiments, a chuck assembly may include a chuck holding a substrate, the substrate being exposed to an ion beam propagating in a vertical direction, a pillar coupled to the chuck to support the chuck, and a connecting portion configured to allow the chuck to be rotatably connected to the pillar. The chuck may have a first axis passing through a center of the chuck in the vertical direction, and the pillar may have a second axis passing through a center of the pillar in the vertical direction. The connecting portion may be configured to allow the first axis to be inclined with respect to the second axis, when the connecting portion is rotated, and at least one of the connecting portion and the pillar may be configured to allow the first axis to undergo a precessional motion about the second axis.

In some embodiments, the connecting portion may be configured to allow the first axis to undergo a precessional motion the second axis in a state of being inclined with respect to the second axis, when the connecting portion is rotated.

In some embodiments, the connecting portion and the pillar may rotate to allow the first axis to undergo a precessional motion about the second axis, in a state of being inclined with respect to the second axis.

According to some embodiments, a chuck assembly may include a chuck to hold a substrate, a pillar coupled to the chuck to support the chuck, an axis of the pillar passing through a center of the pillar in a longitudinal direction of the pillar, and a connecting portion connecting the chuck to the pillar, an axis of the chuck being rotatable on the connecting portion around the axis of the pillar.

A central axis of the chuck may be normal to a top surface of the chuck, the chuck being rotatable around the axis of the pillar while having its central axis inclined with respect to the axis of the pillar.

The chuck may be movable with respect to the connecting portion, while an angle between a top surface of the chuck and the axis of the pillar is an oblique angle.

The connecting portion may be fixed to the pillar, and the chuck is movable on the connecting portion.

A portion of the connecting portion contacting the chuck may have a spherical shape, the chuck being movable along the spherical shape.

According to some embodiments, a semiconductor fabrication system may include an ion beam source configured to generate plasma and extract an ion beam from the plasma, a process chamber connected to the ion beam source and configured to load a substrate, and a chuck assembly configured to hold the substrate and rotate the substrate in an inclined state. The chuck assembly may include a chuck configured to hold the substrate, a pillar coupled to the chuck to support the chuck, and a connecting portion rotatably connecting the chuck to the pillar. The connecting portion may be configured to allow the chuck to be inclined with respect to an axis of the pillar passing through a center of the pillar in a longitudinal direction of the pillar, when the connecting portion is rotated. Also, the chuck may be configured to undergo a precessional motion about the axis of the pillar.

In some embodiments, the chuck assembly may be configured to allow a center of the substrate to revolve around the axis of the pillar.

In some embodiments, the chuck assembly may be configured to allow a center of the substrate to be located on the axis of the pillar.

In some embodiments, the ion beam source may be configured to revolve around the pillar at an inclination angle inclined with respect to the axis of the pillar.

In some embodiments, the ion beam source may be configured to allow the inclination angle to be changed during the ion beam source revolves around the pillar.

In some embodiments, the ion beam source may be configured to have the inclination angle that is fixed during the ion beam source revolves around the pillar.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic diagram of a semiconductor fabrication system according to some embodiments.

FIG. 2A illustrates a perspective view of a chuck assembly according to some embodiments.

FIG. 2B illustrates a perspective view of the chuck assembly of FIG. 2A, in which a chuck is at an inclined state.

FIG. 2C illustrates a diagram of some stages of a chuck of the chuck assembly of FIG. 2A, when the chuck undergoes a precessional motion.

FIG. 2D illustrates a diagram of a precession path of a chuck axis of the chuck assembly of FIG. 2A.

FIG. 3A illustrates a perspective view of a chuck assembly according to some embodiments.

FIG. 3B illustrates a perspective view of the chuck assembly of FIG. 3A, in which a chuck is at an inclined state.

FIG. 3C illustrates a diagram of some stages of a chuck of the chuck assembly of FIG. 3A, when the chuck undergoes a precessional motion.

FIG. 3D illustrates a diagram of a precession path of a chuck axis of the chuck assembly of FIG. 3A.

FIG. 3E illustrates a perspective view of a modification of FIG. 3B.

FIG. 3F illustrates a perspective view of a modification of FIG. 3C.

FIG. 4A illustrates a perspective view of an orbital revolution of an ion beam source in a semiconductor fabrication system according to some embodiments.

FIG. 4B illustrates a perspective view of a modification of FIG. 4A.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on,” etc.). Like numbers indicate like elements throughout.

It should be noted that the drawing figures are intended to illustrate the general characteristics of methods, structure and/or materials utilized in certain example embodiments and to supplement the written description provided below. These drawings are not, however, to scale and may not precisely reflect the precise structure or performance characteristics of any given embodiment, and should not be interpreted as limiting the range of values or properties encompassed by example embodiments.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. As used herein the term “and/or” includes any and all combinations of one or more of the associated listed items.

Unless otherwise defined, all terms (including technical and scientific terms) used herein have the same meaning as commonly understood by one of skill in the art. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

### Semiconductor Fabrication System

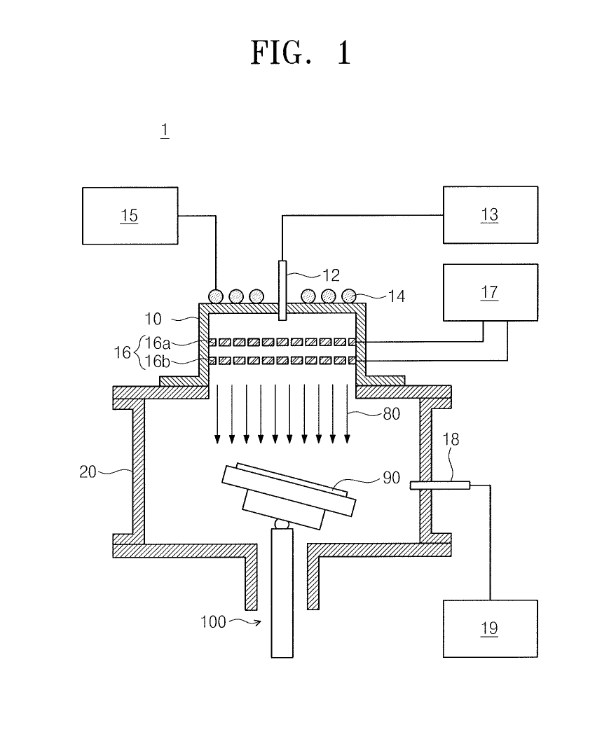

FIG. 1 illustrates a schematic diagram of a semiconductor fabrication system according to some embodiments.

Referring to FIG. 1, a semiconductor fabrication system 1 may include a process chamber 20 and a chuck assembly 100, on which a substrate 90 is loaded. For example, the semiconductor fabrication system 1 may be an ion beam etching system including an ion beam source 10 with a first gas storage 13. The first gas storage 13 may contain a first gas, and the first gas may be supplied into the ion beam source 10 through a gas-supplying inlet 12. The first gas may include, e.g., at least one of ionizable reaction gases including an inert gas (e.g., argon (Ar)), oxygen (O₂), or a mixture thereof In some embodiments, the first gas may further include a process gas (e.g., difluoroacetylene (C₂F₂)). A second gas storage 19 may contain a second gas, and the second gas may be supplied into the process chamber 20 through a gas-supplying inlet 18. The second gas may include a process gas (e.g., C₂F₂).

A radio frequency (RF) power 15 may be configured to apply an RF power (e.g., of about 500 W to about 5 KW) to the first gas supplied into the ion beam source 10 through a loop coil 14 electrically connected thereto, and thus, plasma may be generated in the ion beam source 10. At least one grid 16 with a plurality of holes may be provided in the ion beam source 10. A voltage supplying part 17 may be provided to apply a voltage to the grid 16 and thereby to separate an ion beam 80 from the plasma. The ion beam 80 may propagate in a vertical direction by the applied voltage. As an example, the grid 16 may include a first grid 16a, to which a pulsed positive voltage is applied, and a second grid 16b, to which a pulsed negative voltage is applied.

In some embodiments, when the propagation direction of the ion beam 80 is fixed (e.g., in the vertical direction), the ion beam 80 may be directed toward the substrate 90 on the chuck assembly 100. The chuck assembly 100 may adjust the substrate 90, e.g., to be inclined, with respect to the propagation direction of the ion beam 80 and be rotated or precessed about its inclined axis, as will be described in more detail below.

### Exemplary Embodiments of Chuck Assembly

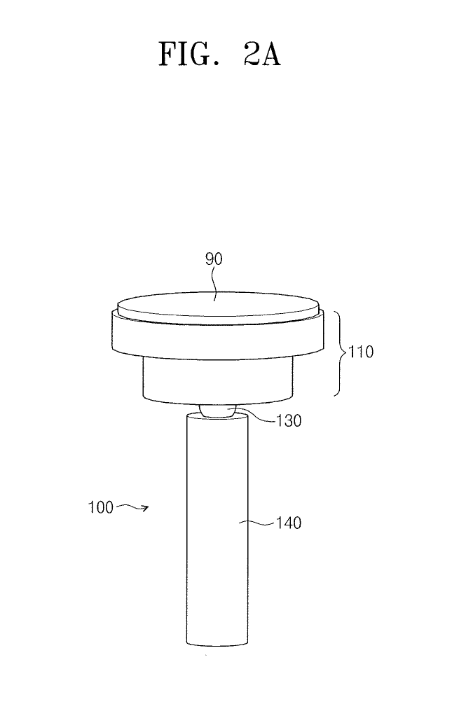

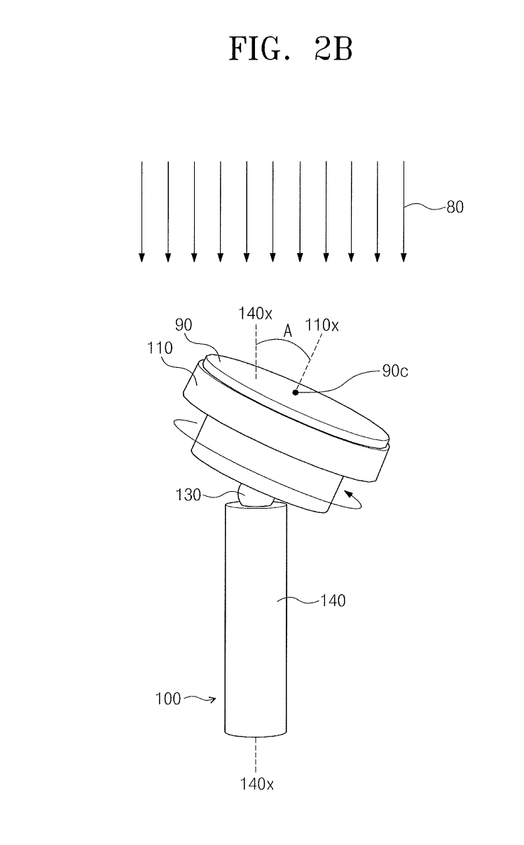

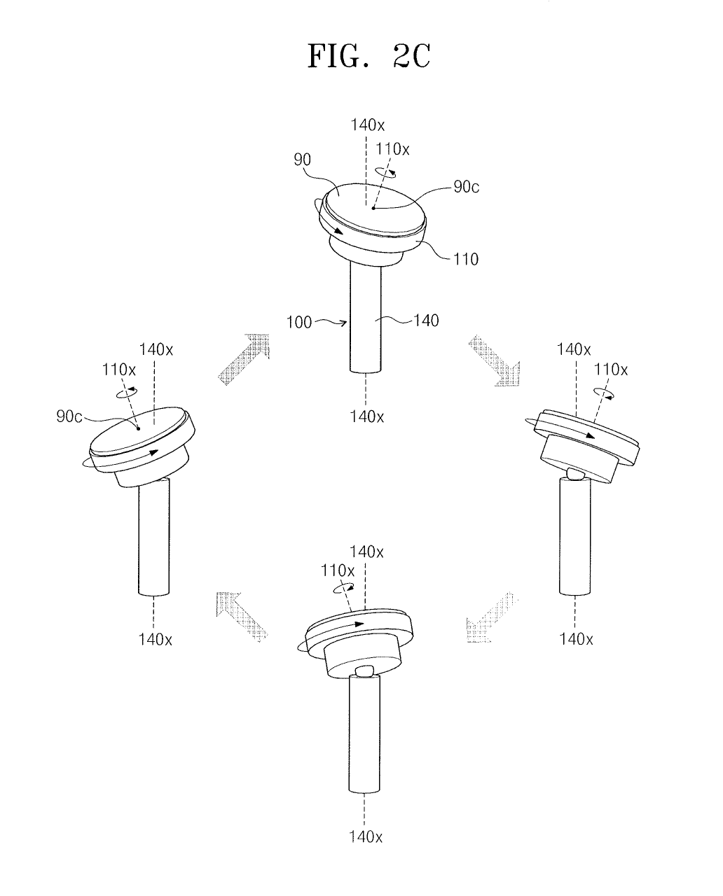

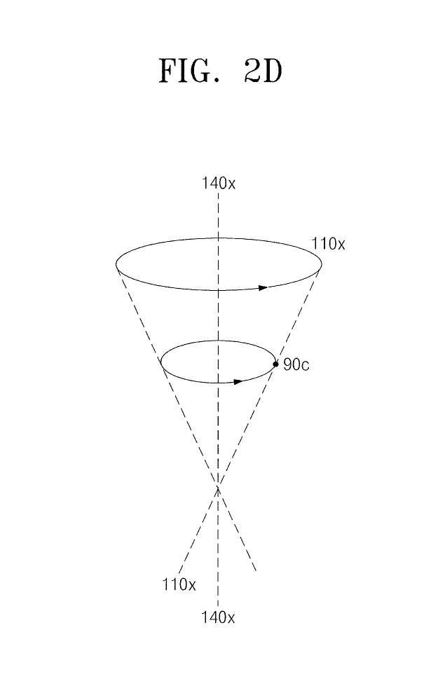

FIG. 2A illustrates a perspective view of a chuck assembly according to some embodiments, and FIG. 2B illustrates a perspective view of the chuck assembly of FIG. 2A, in which a chuck is in an inclined state. FIG. 2C illustrates a diagram of some stages of a chuck of the chuck assembly of FIG. 2A, when the chuck undergoes a precessional motion, and FIG. 2D illustrates a diagram of a precession path of a chuck axis of the chuck assembly of FIG. 2A.

Referring to FIG. 2A, the chuck assembly 100 may include a chuck 110 holding the substrate 90, a pillar 140 supporting the chuck 110, and a connecting portionconnecting the chuck 110 to the pillar 140. The chuck 110 may be one of an electrostatic chuck, a vacuum chuck, and a clamping chuck. The connecting portion may include a rotation part 130. The rotation part 130 may be rotatable around one of the chuck 110 and the pillar 140 and may be fixed to the other. For example, the rotation part 130 may be rotatably connected to a top portion of the pillar 140, while being fixedly connected to a bottom portion of the chuck 110. The rotation part 130 may be provided to have a ball-shaped or spherical structure. The pillar 140 may be provided to have a hollow pipe structure.

Referring to FIG. 2B, the pillar 140 may be provided to have a non-rotatable or fixed structure, whereas the rotation part 130 may be provided to have a rotatable structure. In the case where the pillar 140 is fixed and the rotation part 130 is rotatable, the chuck 110 may be inclined, e.g., tilted, with respect to a pillar axis 140x. which passes through a center of the pillar 140 and is parallel to a longitudinal direction of the pillar 140. Accordingly, a chuck axis 110x, which passes through a center of the chuck 110 in a direction normal to a top surface of the chuck 110, may be inclined with respect to the pillar axis 140x. The chuck 110 may rotate on its axis (i.e., the inclined chuck axis 110x), and the chuck axis 110x may revolve around the pillar axis 140x, as shown in FIG. 2C. An angle A between the pillar axis 140x and the chuck axis 110x may be selected within a range from 0 to 90 degrees.

A center 90c of the substrate 90 may be located on the chuck axis 110x. Thus, the substrate 90 may rotate on the chuck axis 110x, as shown in FIG. 2C, and the center 90c of the substrate 90 may revolve around the pillar axis 140x, as shown in FIG. 2D. During the rotation of the chuck 110, the chuck axis 110x may revolve around the pillar axis 140x, as shown in FIG. 2D. In other words, the chuck assembly 100 may be configured to allow for the precession of the chuck 110. Furthermore, the precession of the chuck 110 may lead to precession of the substrate 90 on the chuck. The ion beam 80 may be incident onto the substrate 90 in precession. In the case where an etching process is performed using the chuck assembly 100, patterns on the substrate 90 may be formed to have a profile perpendicular to a top surface of the substrate 90. In some embodiments, the angle A between the pillar axis 140x and the chuck axis 110x may be fixed, but in certain embodiments, the angle A may be periodically or intermittently changed during the rotational and revolving motion of the chuck 110.

In some embodiments, since the center 90c of the substrate 90 revolves around the pillar axis 140x, it is possible to increase an area of a region to be swept by the movement of the substrate 90. Accordingly, even if there is a spatial variation in density of the ion beam 80, it is possible to realize high process uniformity in a process (e.g., an etching process) on the substrate 90. For example, referring back to FIG. 2B, the density of the ion beam 80 may be high at the pillar axis 140x and low at an edge region of the substrate 90. However, the density of the ion beam 80 may be periodically changed at each point of the substrate 90, and this may make it possible to increase the process uniformity in the process (e.g., etching process) using the ion beam 80.

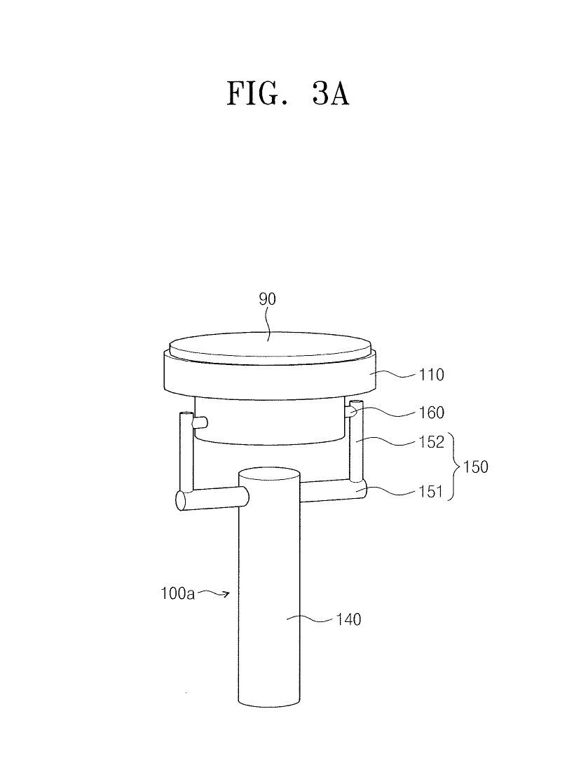

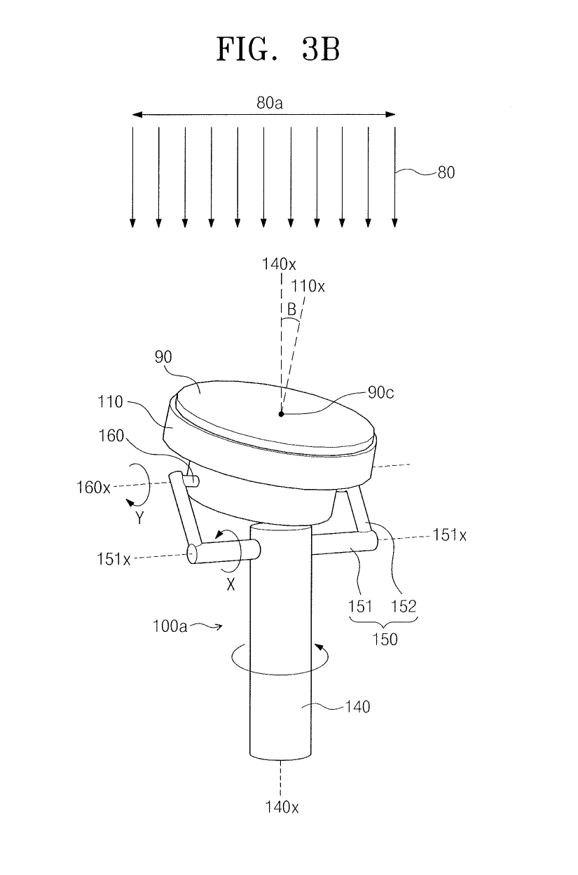

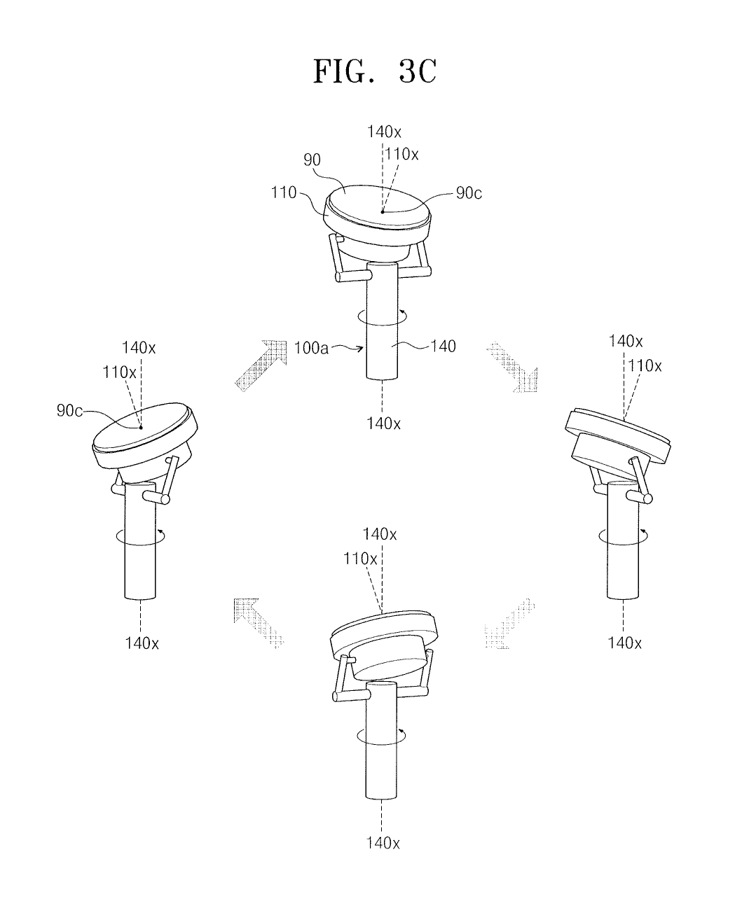

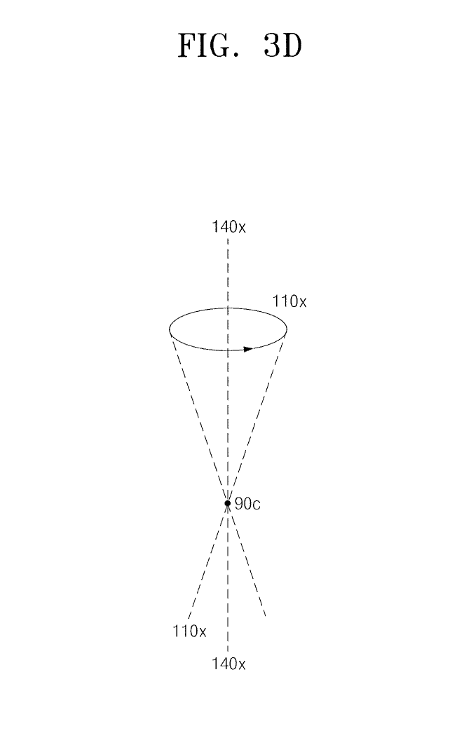

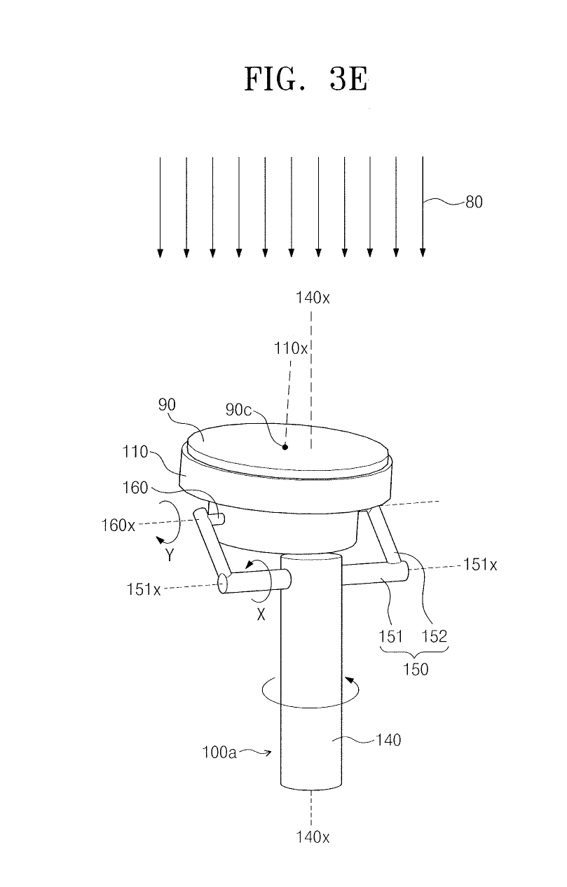

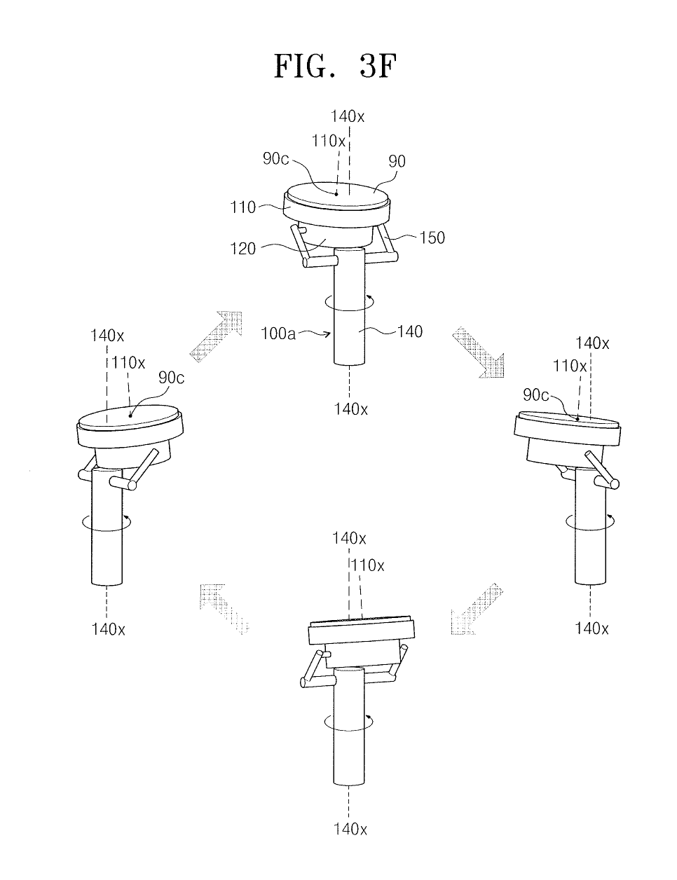

In another example, the chuck 110 may have a non-rotatable or fixed structure, while the pillar 140 may be configured to be rotatable about the pillar axis 140x. In this case, the chuck 110 may be configured to have substantially the same or similar features as that described with reference to FIGS. 2B through 2D, except that the rotation of the chuck 110 is not allowed. This will be described in more detail with reference to FIGS. 3A-3F.

FIG. 3A illustrates a perspective view of a chuck assembly according to some embodiments, and FIG. 3B illustrates a perspective view of the chuck assembly of FIG. 3A, in which a chuck is in an inclined state. FIG. 3C illustrates a diagram of some stages of a chuck of the chuck assembly of FIG. 3A, when the chuck undergoes a precessional motion, and FIG. 3D illustrates a diagram of a precession path of a chuck axis of the chuck assembly of FIG. 3A. FIG. 3E illustrates a perspective view of a modification of FIG. 3B, and FIG. 3F illustrates a perspective view of a modification of FIG. 3C.

Referring to FIG. 3A, a chuck assembly 100a may include the chuck 110 holding the substrate 90, the pillar 140 supporting the chuck 110, and a connecting portion connecting the chuck 110 to the pillar 140. The connecting portion may include a supporting frame 150 supporting the chuck 110, and a horizontal rod 160 connecting the supporting frame 150 to the chuck 110 and horizontally passing through the chuck 110. The supporting frame 150 may include a horizontal frame 151, which is provided to pass through a top portion of the pillar 140 in a horizontal direction, and a vertical frame 152, which is connected to two opposite ends of the horizontal frame 151. The horizontal rod 160 may be provided to be rotatable about the chuck 110 and the vertical frame 152, respectively. Alternatively, the horizontal rod 160 may be fixedly coupled to the chuck 110 and may be configured to be rotatable about the vertical frame 152.

Referring to FIG. 3B, the pillar 140 may be configured to be rotatable about its axis, i.e., about the pillar axis 140x. The chuck 110 may be configured to be rotatable about the horizontal rod 160, i.e., about axis 160x. The pillar 140 and the supporting frame 150 may be configured to allow the supporting frame 150 to be rotatable about an axis 151x. Under this configuration, in the case where the supporting frame 150 is rotated about the axis 151x in a counterclockwise direction X, and the chuck 110 is rotated about the horizontal rod 160 in a clockwise direction Y, the substrate 90 may be inclined with respect to the propagation or injection direction of the ion beam 80. Accordingly, the chuck axis 110x may also be inclined with respect to the pillar axis 140x. An angle B between the pillar axis 140x and the chuck axis 110x may be selected within a range from 0 to 90 degrees.

The rotation angles in the counterclockwise and clockwise directions X and Y may be adjusted to allow the center 90c of the substrate 90 to be placed on the pillar axis 140x. In the case where, as shown in FIG. 3C, the pillar 140 rotates on the pillar axis 140x, the chuck 110 may rotate on the pillar axis 140x in the inclined state. This may be true for the substrate 90. Likewise, since the substrate 90 rotates on the center 90c, it is possible to reduce a distribution or beam size 80a of the ion beam 80, and consequently, to reduce a size or volume of the semiconductor fabrication system 1 of FIG. 1.

In some embodiments, the chuck axis 110x may revolve around the pillar axis 140x, as shown in FIG. 3D. For example, the chuck assembly 100a may be configured to allow for the precession of the chuck 110. The substrate 90 may rotate on its axis or the center 90c that is inclined with respect to the pillar axis 140x.

Alternatively, as shown in FIG. 3E, the rotation angles of the supporting frame 150 and the chuck 110 may be adjusted to allow the center 90c of the substrate 90 to be placed at a position spaced apart from the pillar axis 140x. In this case, as shown in FIG. 3F, the rotation of the pillar 140 on the pillar axis 140x may lead to revolution of the center 90c of the substrate 90 around the pillar axis 140x.

ORBITAL REVOLUTION OF ION BEAM SOURCE

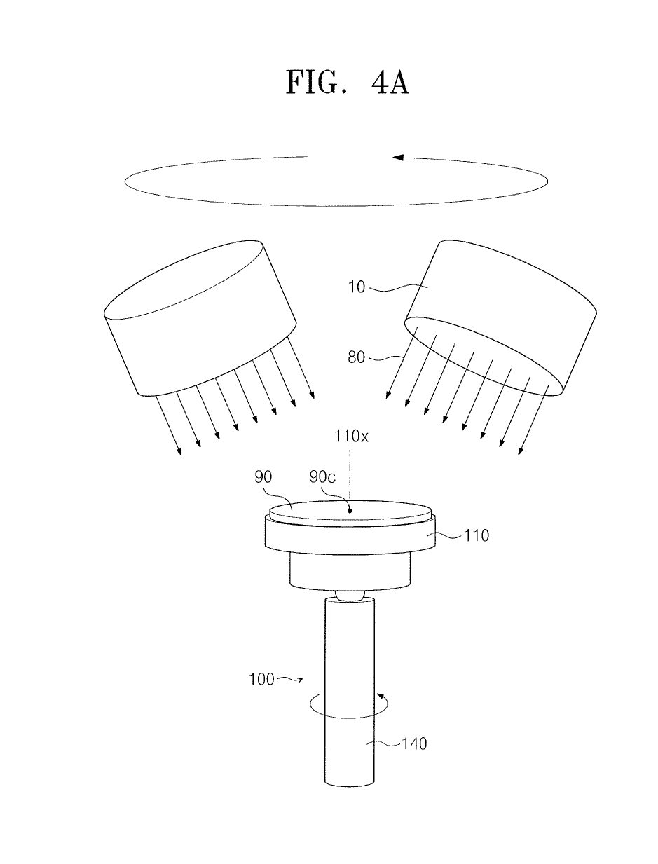

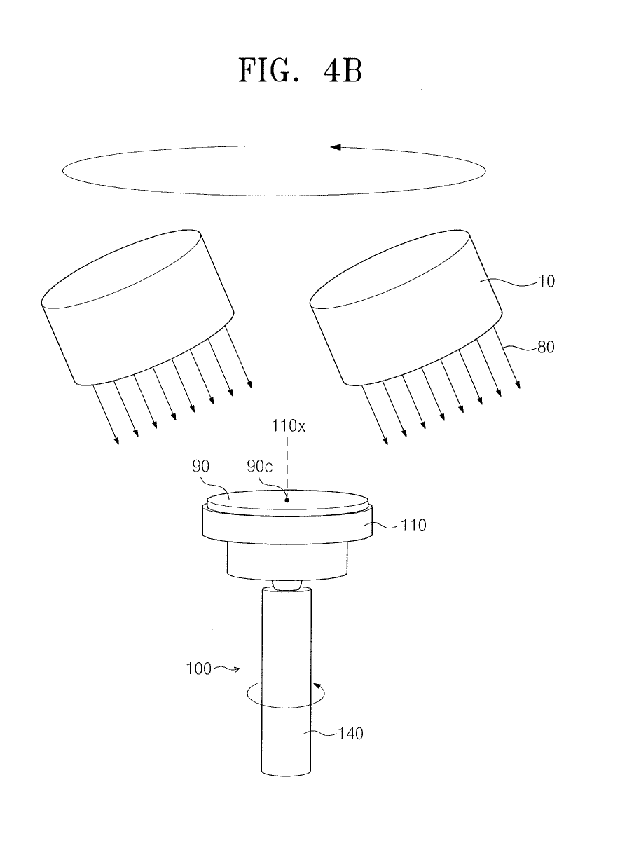

FIG. 4A illustrates a perspective view schematically of an orbital revolution of an ion beam source in a semiconductor fabrication system according to some embodiments. FIG. 4B illustrates a perspective view of a modification of FIG. 4A.

Referring to FIG. 4A, the substrate 90 may be disposed to have a top surface perpendicular to the pillar axis 140x, and the ion beam source 10 may be disposed to revolve around the pillar axis 140x at an angle inclined with respect to the pillar axis 140x. For example, the ion beam source 10 may be configured to emit the ion beam 80 toward the substrate 90, while revolving around the chuck axis 110x of the chuck 110 passing through the center 90c of the substrate 90. During the revolution of the ion beam source 10 around the chuck axis 110x, the inclined angle of the ion beam source 10 may be changed to allow the ion beam 80 to be emitted toward the substrate 90. The pillar 140 may be configured to be able to rotate on its axis (e.g., the pillar axis 140x), but embodiments are not limited thereto. As shown in FIG. 4B, the inclined angle of the ion beam source 10 may be fixed, during the revolution of the ion beam source 10 around the chuck axis 110x.

The chuck assembly 100 or 100a may be used for the semiconductor fabrication system 1 with an inductively-coupled plasma (ICP) system of FIG. 1, but embodiments are not be limited thereto. For example, the chuck assembly 100 or 100a may be used for any plasma-using semiconductor fabrication system (e.g., an etching or deposition system with a capacitively coupled plasma (CCP) system or a remote plasma system).

By way of summation and review, there is an increasing demand for a chuck assembly capable of easily changing a tilting angle of a chuck and achieving high etching uniformity. Therefore, according to some embodiments, it is possible to, e.g., constantly, change a tilting angle of a chuck by having the chuck undergo a precessional motion, and thereby to realize high process uniformity in an etching process, e.g., minimize asymmetry at an edge. This may make it possible to increase a process yield.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A chuck assembly, comprising:
a chuck to hold a substrate; and
a pillar coupled to the chuck to support the chuck, an axis of the pillar passing through a center of the pillar in a longitudinal direction of the pillar,
wherein the chuck has a top surface, which is inclined with respect to the axis of the pillar, the top surface of the chuck being precessionally rotatable about the axis of the pillar.

2. The chuck assembly as claimed in claim 1, wherein the chuck has an axis passing through a center of the chuck, and the axis of the chuck is inclined with respect to the axis of the pillar.

3. The chuck assembly as claimed in claim 2, wherein the axis of the chuck is precessionally rotatable around the axis of the pillar while being inclined with respect to the axis of the pillar.

4. The chuck assembly as claimed in claim 2, wherein the chuck is rotatable around the axis of the chuck.

5. The chuck assembly as claimed in claim 2, wherein the axis of the chuck is aligned with a center of the substrate disposed on the chuck.

6. The chuck assembly as claimed in claim 5, wherein the chuck is arranged to have the center of the substrate revolve around the axis of the pillar.

7. The chuck assembly as claimed in claim 5, wherein the center of the substrate is aligned with the axis of the pillar.

8. The chuck assembly as claimed in claim 2, wherein the pillar is rotatable around the axis of the pillar.

9. The chuck assembly as claimed in claim 1, further comprising a connecting portion connecting the chuck to the pillar, the connecting portion being rotatable about the pillar,
wherein the connecting portion is fixedly connected to the chuck, and
wherein an angle between the axes of the chuck and the pillar is controllable by changing a rotation angle of the connecting portion.

10. The chuck assembly as claimed in claim 1, further comprising a connecting portion connecting the chuck to the pillar, the connecting portion being rotatable about the pillar, and an angle between the axes of the chuck and the pillar being adjustable via the connecting portion.

11 The chuck assembly as claimed in claim 10, wherein the connecting portion includes a supporting frame, the supporting frame including:
a horizontal frame passing through the pillar in a direction orthogonal to the axis of the pillar; and
a vertical frame on opposite ends of the horizontal frame, the vertical frame extending parallel to the axis of the pillar and being rotatable about an axis of the horizontal frame.

12. The chuck assembly as claimed in claim 11, further comprising a horizontal rod connecting the supporting frame to the chuck, the horizontal rod passing through the chuck in a direction orthogonal to the axis of the chuck, and the chuck being rotatable about the horizontal rod.

13.-19. (canceled)

20. A chuck assembly, comprising:
a chuck to hold a substrate, the substrate being exposed to an ion beam propagating in a vertical direction;
a pillar coupled to the chuck to support the chuck; and
a connecting portion rotatably connecting the chuck to the pillar,
wherein the chuck has a first axis passing through a center of the chuck in the vertical direction, and the pillar has a second axis passing through a center of the pillar in the vertical direction,
wherein the connecting portion is rotatable to arrange the first axis to be inclined with respect to the second axis, and
wherein at least one of the connecting portion and the pillar is arranged to allow the first axis to undergo a precessional motion about the second axis.

21. The chuck assembly as claimed in claim 20, wherein the connecting portion is rotatable to arrange the first axis to undergo a precessional motion about the second axis, the first axis being in a state of being inclined with respect to the second axis.

22. The chuck assembly as claimed in claim 20, wherein the connecting portion and the pillar are rotatable to arrange the first axis to undergo a precessional motion about the second axis, the first axis being in a state of being inclined with respect to the second axis.

23. A chuck assembly, comprising:
a chuck to hold a substrate;
a pillar coupled to the chuck to support the chuck, an axis of the pillar passing through a center of the pillar in a longitudinal direction of the pillar; and
a connecting portion connecting the chuck to the pillar, an axis of the chuck being rotatable on the connecting portion around the axis of the pillar.

24. The chuck assembly as claimed in claim 23, wherein a central axis of the chuck is normal to a top surface of the chuck, the chuck being rotatable around the axis of the pillar while having its central axis inclined with respect to the axis of the pillar.

25. The chuck assembly as claimed in claim 23, wherein the chuck is movable with respect to the connecting portion, while an angle between a top surface of the chuck and the axis of the pillar is an oblique angle.

26. The chuck assembly as claimed in claim 23, wherein the connecting portion is fixed to the pillar, and the chuck is movable on the connecting portion.

27. The chuck assembly as claimed in claim 26, wherein a portion of the connecting portion contacting the chuck has a spherical shape, the chuck being movable along the spherical shape.

28.-33. (canceled)
